(19) United States
(12) Patent Application Publication
(10) Pub. No.: US 2009/0308581 A1
(43) Pub. Date: Dec. 17, 2009

(54) HEAT SINK

(75) Inventors: Yoshiro Tanaka, Kawasaki (JP); Hisashi Yoshinaga, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/547,161

(22) Filed: Aug. 25, 2009

Related U.S. Application Data
(63) Continuation of application No. PCT/JP2007/056891, filed on Mar. 29, 2007.

(51) Int. Cl. H05K 7/20; F28F 7/00

(52) U.S. Cl. 165/121; 165/185

(57) ABSTRACT

The heat sink include a conductive heat dissipation portion for dissipating heat of an electronic component into the air, and a current limitation portion arranged on the heat dissipation surface of the heat dissipation portion and limiting a discharge current flowing between a material object located in proximity to the heat dissipation surface and the heat dissipation portion when discharge phenomenon takes place between the material object and the heat dissipation portion.

### CROSS-REFERENCE TO RELATED APPLICATIONS

This is a continuation of Application PCT/JP2007/056891, filed on Mar. 29, 2007, now pending, the contents of which are herein wholly incorporated by reference.

### FIELD

The embodiments discussed herein are relates to a heat sink which radiates heat of an electronic component.

### BACKGROUND

The electronic component generates heat when an electric current flows to a semiconductor element etc. The electronic component has a possibility of causing a malfunction and a decline of performance when a temperature rises over a design value, and is therefore fitted with a cooling device such as a heat sink.

For example, Patent document 1 describes a technology of enhancing performance of transferring the heat to a cooling body by reducing a thickness of an electrode of portions with a power transistor and a diode interposed therebetween. Further, Patent document 2 describes a technology of blowing the cooling air uniformly to an exothermic body by adjusting a flow of the cooling air with a louver. Still further, Non-Patent document 1 exemplifies shapes of a variety of heat sinks. Yet further, Non-Patent documents 2 and 3 describe heat sink selecting methods or heat sink design methods.

[Patent document 1] Japanese Patent Laid-Open Publication No. 2006-229180

[Patent document 2] Japanese Patent Laid-Open Publication No. 2004-31504

[Non-Patent document 1] Marusan Electronics co., Ltd.

[Non-Patent document 2] Mizutani Electric Industry Co., Ltd (No. 1).

[Non-Patent document 3] Mizutani Electric Industry Co., Ltd (No. 2).

### SUMMARY

A heat sink includes: a conductive radiating unit radiating heat of an electronic component into the air; and a current restricting unit disposed on a heat sink surface of the radiating unit and restricting, when a discharge phenomenon occurs between a tangible object vicinal to the heat sink surface and the radiating unit, a discharge current flowing to between the tangible object and the radiating unit.

The object and advantage of the embodiment will be realized and attained by means of the elements and combinations particularly pointed out in the claims.

It is to be understood that both the foregoing general description and the following detailed description are exemplary and explanatory only and are not restrictive of the embodiments discussed herein, as claimed.

### BRIEF DESCRIPTION OF THE DRAWINGS

FIG. 1A is a perspective view of a heat sink as viewed obliquely from above according to an embodiment;

FIG. 1B is a perspective view of the heat sink as viewed obliquely from under according to the embodiment;

FIG. 2 is an enlarged sectional view, taken along the line A-A, of a part of a heat sink surface of a heat sink plate according to the embodiment;

FIG. 3 is a view illustrating a flow of electricity when projections restrict a discharge current;

FIG. 4 is a graph representing a relationship between a voltage of a radiating unit and time;

FIG. 5 is a perspective view of a notebook PC mounted with heat sinks;

FIG. 6 is a perspective view of a portion vicinal to a vent hole of the notebook PC as viewed from outside;

FIG. 7 is a view depicting a state of how testing devices are disposed when performing a validation test;

FIG. 8 is a table illustrating a result of the validation test;

FIG. 9 is an enlarged view of a part of the heat sink surface of the heat sink plate according to a modified example; and

FIG. 10 is an enlarged view of a part of the heat sink surface of the heat sink plate according to the modified example.

### DESCRIPTION OF EMBODIMENTS

A heat sink according to a preferred embodiment of the embodiments discussed herein will hereinafter be described with reference to the drawings. The embodiment is an exemplification, and the embodiments discussed herein are not limited to this exemplification.

<Configuration>

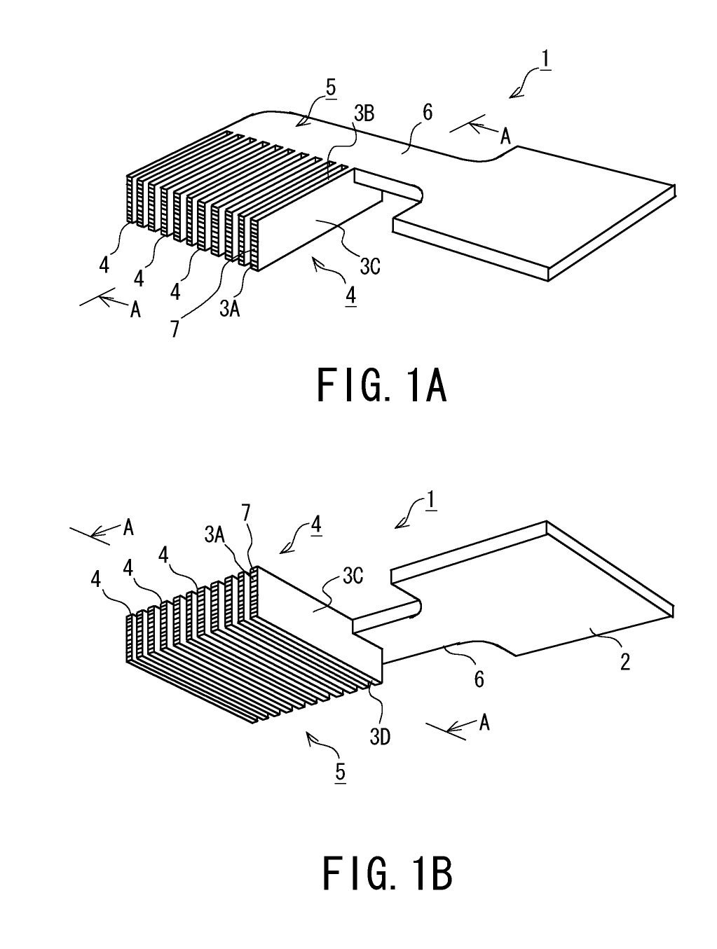

FIGS. 1A and 1B illustrate perspective views of a heat sink 1 according to one embodiment of the embodiments discussed herein. As illustrated in FIGS. 1A and 1B, the heat sink 1 includes a heat transfer surface 2 which exchanges heat with a heat source (e.g., a CPU (Central Processing Unit)), a cooling fin 5 equipped with a multiplicity of heat sink plates 4 each including heat sink surfaces 3A, 3B, 3C, 3D which exchange the heat with the air, and a heat transfer unit 6 which controls the heat transfer between the heat transfer surface 2 and the cooling fin 5. Note that the heat sink 1 is constructed of a heat conductive member such as cooper and aluminum, and has electric conductivity.

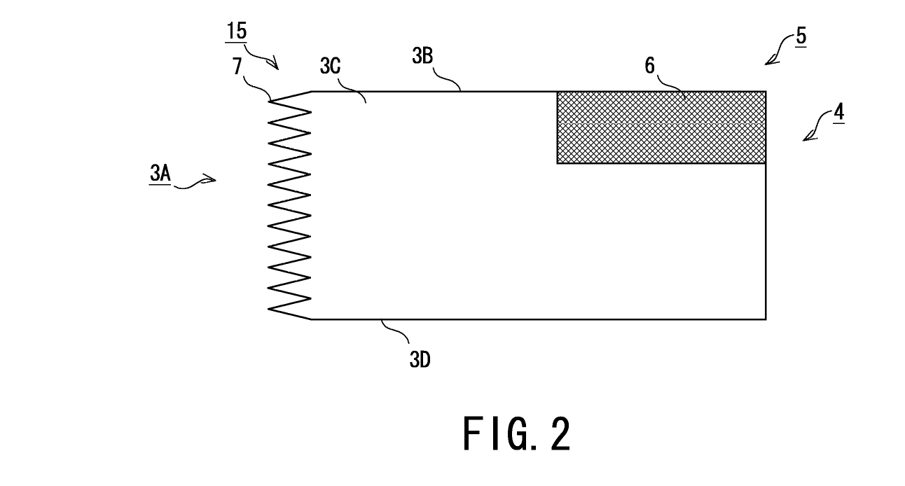

FIG. 2 depicts an enlarged sectional view, taken along the line A-A, of a portion vicinal to the heat sink surface 3A of the heat sink plate 4. As illustrated in FIG. 2, the heat sink surface 3A of the heat sink plate 4 is provided with a current restricting unit 15 including a multiplicity of projections 7 arranged for restricting, if an electric discharge phenomenon occurs between the cooling fin 5 and a tangible object existing in the vicinity of the cooling fin 5, this discharge current flowing to between the tangible object and the cooling fin 5. The multiplicity of projections 7 is formed by, e.g., notching the heat sink surface 3A with a cutter or the like. Note that the projections 7 may be formed beforehand by a die for molding the cooling fin 5 and may also be formed by press working or laser working executed on the heat sink surface 3A.

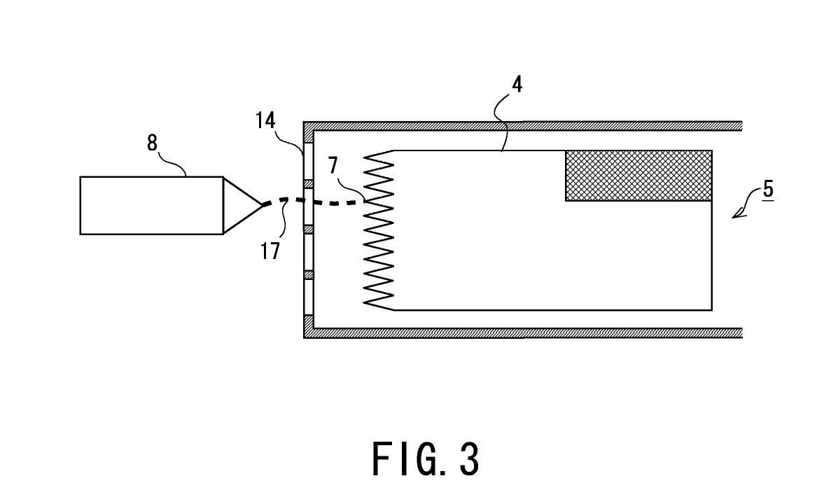

FIG. 3 illustrates an electric flow when the projections 7 restrict the discharge current. As illustrated in FIG. 3, when a potential difference between the cooling fin 5 and a tangible object 8 (which is, e.g., a part of a table or human body) existing in the vicinity of the cooling fin 5 exceeds a dielectric breakdown voltage in the air between the tangible object 8 and the cooling fin 5, a discharge phenomenon 17 occurs between the tangible object 8 and the cooling fin 5. The lowest dielectric breakdown voltage between the tangible object 8 and the cooling fin 5 occurs at the shortest distance in the air between a tip of the projection 7 and the tangible object 8. Hence, when the potential difference between the tangible object 8 and the cooling fin 5 rises, the discharge phenomenon occurs fastest between the tip of the projection 7 and the tangible object 8.

Herein, as depicted in FIG. 3, the tip of the projection 7 is shaped extremely thin. Therefore, the projection 7, though composed of a conductive metal material, restricts the current to some extent, which is enabled to flow from the tip thereof. Accordingly, when the discharge phenomenon occurs between the tangible object 8 and the cooling fin 5, the tip of the projection 7 via which the excessive discharge current flows performs a function as a resistance, thereby restricting the current flowing to the cooling fin 5. Thus, when the discharge phenomenon occurs between the tangible object 8 and the cooling fin 5, the current flowing to the cooling fin 5 is restricted, with the result that the discharge voltage is hard to transfer to the heat source such as the CPU via the heat transfer unit 6 and the heat transfer surface 2.

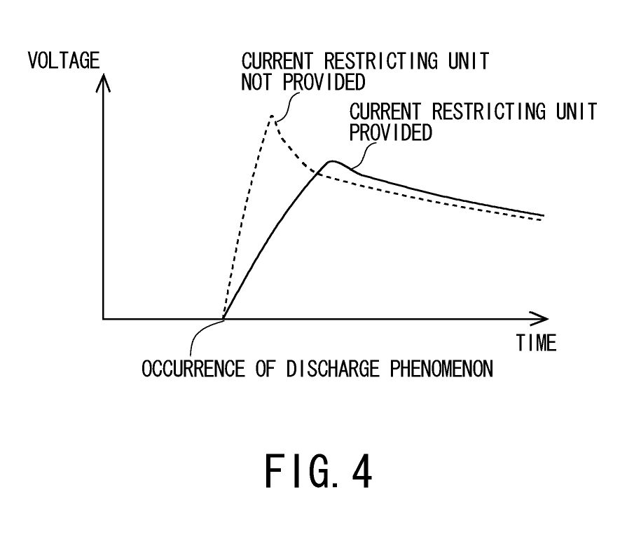

FIG. 4 illustrates a graph representing a relationship between the voltage of the cooling fin 5 and the time in comparison between a case where the electricity is discharged to the heat sink 1 provided with the current restricting unit 15 and a case where the electricity is discharged to the heat sink provided with none of the current restricting unit 15. As depicted in the graph of FIG. 4, the heat sink 1 provided with the current restricting unit 15 restricts the discharge current to thereby restrain the rise in voltage (fluctuation in potential) of the cooling fin 5, and attains a lower maximum value of the voltage than by the heat sink provided with none of the current restricting unit.

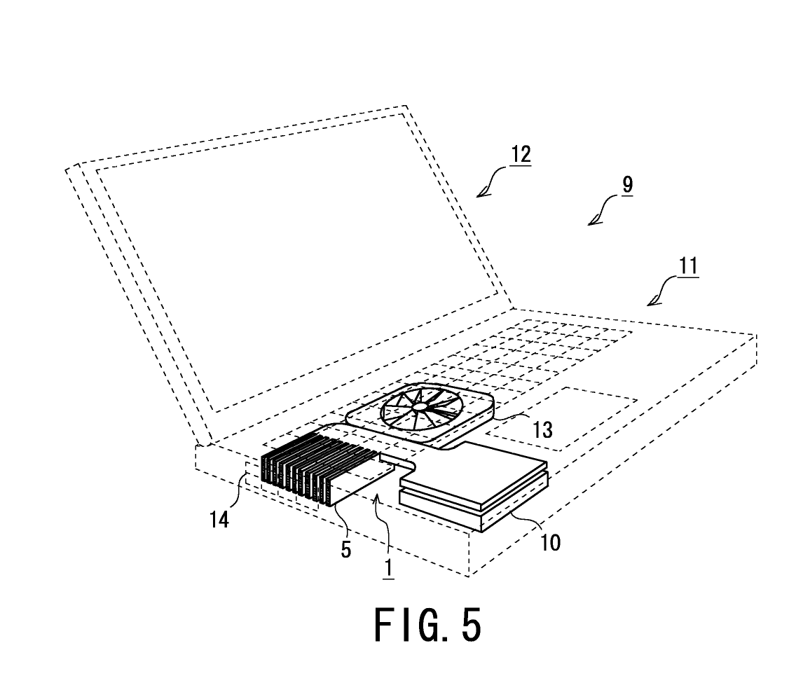

Next, an applied example of the heat sink 1 will be described. FIG. 5 illustrates a perspective view of a notebook type personal computer 9 (which will hereinafter be abbreviated to the notebook PC 9) mounted with the heat sink 1. As illustrated in FIG. 5, the notebook PC 9 is constructed of a body unit 11 including a built-in CPU 10 etc defined as an exothermic source and a display unit 12 including a liquid crystal panel.

The body unit 11 of the notebook PC 9 has the built-in heat sink 1 and a built-in blowing fan 13 which serve for radiating the heat of the CPU 10 to the outside, thereby preventing the CPU 10 from being overheated. As depicted in FIG. 5, the heat sink 1 is disposed so that the heat transfer surface 2 abuts on the CPU 10 and so that the cooling fin 5 is disposed in the vicinity of a vent hole 14. The cooling fin 5 is disposed in the vicinity of the vent hole 14, whereby the heat sink surfaces 3A, 3B, 3C, 3D are exposed to the air and thus cooled down.

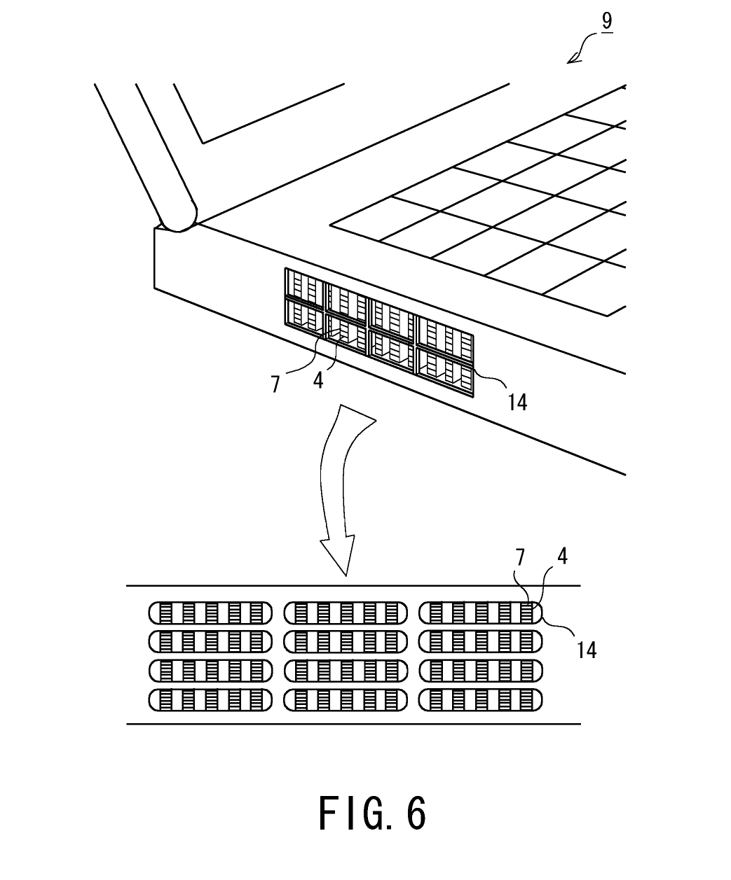

Herein, the cooling fin 5 is disposed in the vicinity of the vent hole 14 and is therefore easy to be affected by electric noises, static electricity, etc, which are generated outside. FIG. 6 illustrates a perspective view of a portion vicinal to the vent hole 14 of the notebook PC 9 as viewed from the outside. As illustrated in FIG. 6, the cooling fin 5 is disposed in a position, which facilitates visual recognition from the outside, in the vicinity of the vent hole 14 of the notebook PC 9. Herein, for example, if a user with the static electricity touches the portion vicinal to the vent hole 14 of the notebook PC 9, the discharge phenomenon occurs between the user and the cooling fin 5. Such being the case, the heat sink 1 according to the embodiment is disposed within the notebook PC 9 so that the projections 7 restricting the discharge current take a posture directed to the outside of the vent hole 14.

<Effect>

From what has been discussed so far, the heat sink 1 according to the embodiment, even when the cooling fin 5 is disposed in such a position as the vent hole 14 which easily admits an inflow of the electricity from the outside, restricts the discharge current inputted to the cooling fin 5, whereby the electric influence on the electronic components electrically connecting with the heat sink 1 can be reduced. Especially, the discharge current is restricted in a way that works the heat sink surface 3, thereby enabling withstanding voltage characteristics to be improved without any decline of the cooling performance of the heat sink surface 3.

Further, a quality can be maintained by improving tolerance against the electrostatic discharge of the whole device without adding any excessive electrostatic countermeasure members.

Moreover, a scheme of adding none of the excessive electrostatic countermeasure members affects neither an evaluation of the radio waves of the whole device nor an evaluation of the electrostatic discharge of other than the heat sink. Therefore, such a problem is avoided that the electrostatic discharge is reevaluated by retesting the portions other than the heat sink.

Furthermore, the heat sink 1 according to the embodiment eliminates the necessity for additional measures such as pasting, e.g., a radio wave absorbing sheet to the CPU and enables a manufacturing cost of the device to be restrained.

Further, the implementation of the surface process described above leads to an increased surface area of the whole heat sink, thereby ameliorating the cooling efficiency of the heat sink and enhancing the cooling performance.

<Validation Test>

The following is discussion on a testing method and a testing result on the occasion of performing an aerial discharge test about a notebook PC (a notebook PC made by Fujitsu Corp., which will hereinafter be termed a equipment under test (EUT) 1) mounted with the heat sink which does not include the current restricting unit 15 and the notebook PC 9 mounted with the heat sink 1 including the current restricting unit 15. The present validation test conforms to the testing method specified by the International Standard “IEC (International Electrotechnical Commission) 61000-4-2”. This standard intends to evaluate the tolerance of the electronic device against the electrostatic discharge produced from the operator or the ambient tangible object under such a condition as to use clothing etc of synthetic fibers.

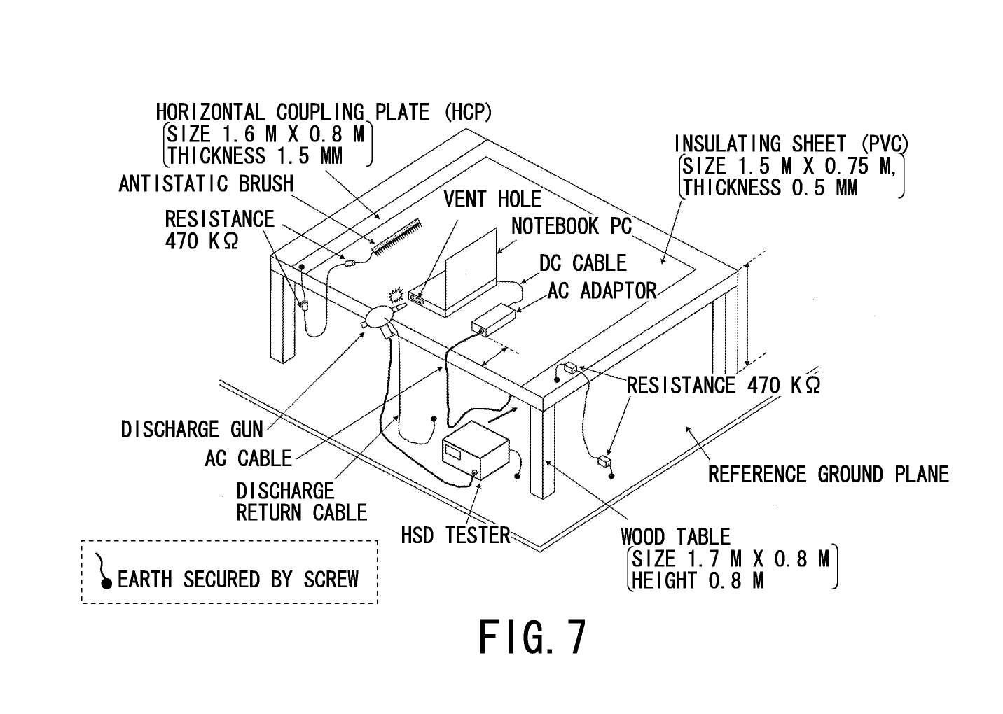

FIG. 7 illustrates a state of how test devices are disposed on the occasion of performing the validation test. As depicted in FIG. 7, an insulating sheet is placed on a wooden table with a horizontal coupling plate interposed therebetween. The notebook PC, a power source cable, an antistatic brush, etc are placed on the insulating sheet. Note that an ESD simulator (ElectroStatic Discharge simulator: ESD simulator 5300 made by BigBang) is installed under the wooden table, and a ground wire of the ESD tester is connected to a ground reference plane. Further, this ground reference plane is electrically connected to the insulating sheet on the wooden table via a resistor. Incidentally, an ESD gun for discharging the electricity connects with the ESD tester.

A person in charge of the test discharges the electricity from a front edge of the ESD gun towards the vent hole of the notebook PC, and samples items of data. The items of data to be sampled are exemplified by a discharge voltage of the electricity discharged from the ESD gun, a discharge peak current and time-variations of the current value. If these items of sampled data satisfy the characteristics specified by the International Standard “IEC 61000-4-2”, the data are determined acceptable. Note that the International Standard “IEC 61000-4-2” specifies the conditions of the withstanding voltage characteristics stepwise corresponding to a testing level (i.e., a test voltage when discharging the electricity). Hence, the validation test according to the embodiment involves increasing the test level of the discharge test stepwise with respect to an EUT 1 and an EUT 2 and checking each discharge voltage enabling the IEC Standard to be satisfied.

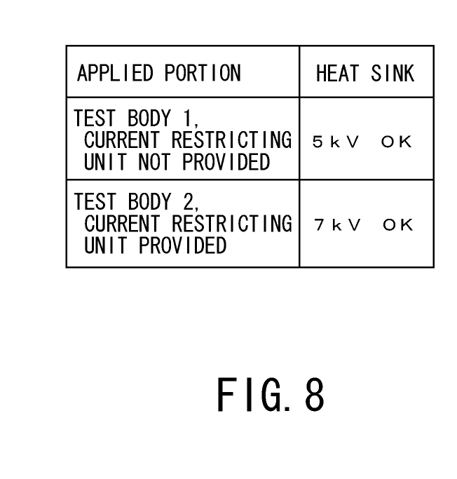

FIG. 8 illustrates a result of the validation test. In the validation test, as a result of checking the discharge voltage enabling the IEC Standard to be satisfied with respect to each of the EUT 1 and the EUT 2, it is confirmed that the EUT 1 meets the acceptable standard up to a discharge voltage of 5 kV, while the EUT 2 meets the acceptable standard up to a discharge voltage of 7 kV. Namely, when the embodiments discussed herein are applied, the confirmation is that a yield stress with respect to the electrostatic aerial discharge is improved on the order of 2 kV-3 kV. Accordingly, the validation test demonstrated that the electric influence on the electronic device is reduced to a greater degree in the case of providing the current restricting unit according to the embodiments discussed herein than by the heat sink which is not provided with the current restricting unit.

### Modified Example

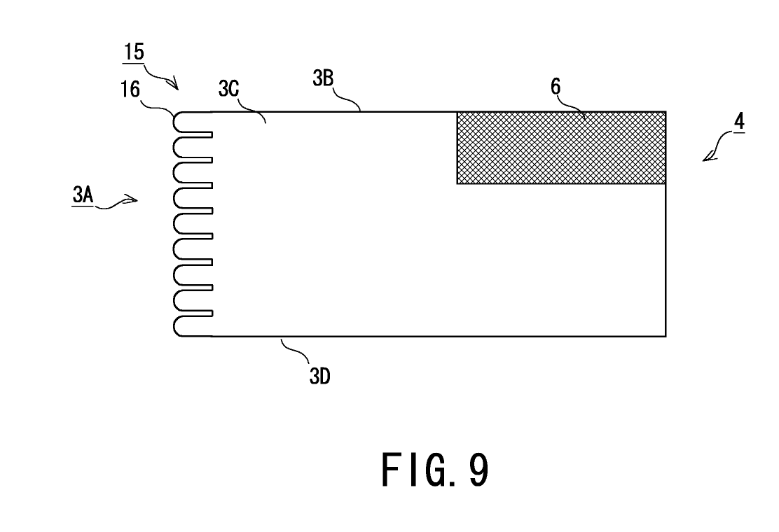

Note that the current restricting unit 15 in the embodiment discussed above is configured with the projections including the sharp-pointed tips, however, the embodiments discussed herein are not limited to this configuration. FIG. 9 illustrates a modified example of the current restricting unit 15. The current restricting unit 15 may be, if the projections are capable of restricting only the discharge current, configured with projections including round-shaped tips as depicted in FIG. 9.

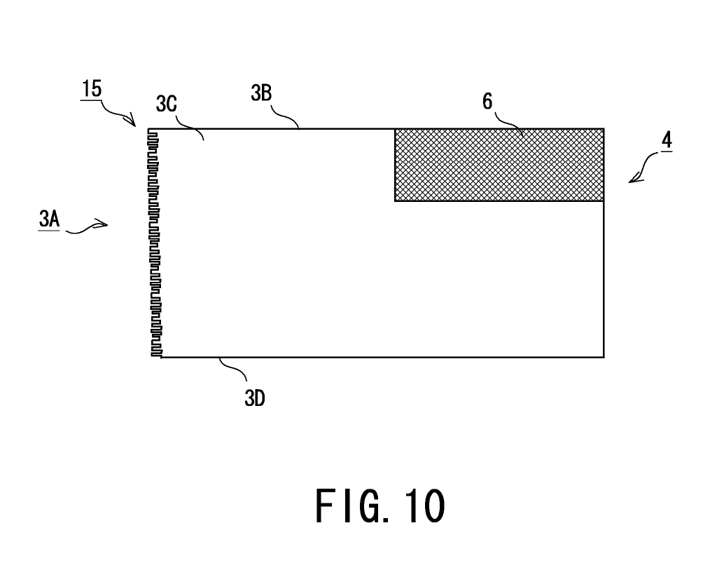

Further, in the embodiments discussed herein, the current restricting unit 15 is not limited to the current restricting unit configured with the projections. FIG. 10 illustrates another modified example of the current restricting unit. As depicted in FIG. 10, the current restricting unit may increase the electric resistance by roughing the heat sink surface in a way that executes rough surface working on the heat sink surface. This rough surface is formed by polishing the heat sink surface with sandpaper etc and executing a sandblasting process on the heat sink surface.

In these modified examples, the discharge current is restricted on the occasion of the occurrence of the discharge phenomenon, and the fluctuations in potential of the radiating unit can be restrained.

It should be noted that the embodiments discussed herein are effective in a scheme of being applied to a portion such as a screw hole and a metallic connector of the notebook PC where the static electricity might be discharged in the air.

Electronic devices nowadays are increasingly hard to take a measure against radio waves (EMI (Electromagnetic Interference) countermeasure) and a measure against static electricity (ESD (Electrostatic Discharge) countermeasure) with speed-up of a clock frequency, high-density packaging of a printed board and a decreased weight of the device. An information apparatus typified by a notebook type personal computer, a printer, etc emits a variety of noises (e.g., broadband noises, narrowband noises, etc) in frequency bands in a broad range due to various semiconductors and interfaces existing inside. On the other hand, a CPU (Central Processing Unit), a chipset, etc are downsized for saving electric power while electromotive force decreases, and tolerance against an electrostatic discharge is lowered. If these noises are not restrained within an allowable value specified by EMC (Electromagnetic Compatibility) regulations, the device can not be shipped. Moreover, the tolerance against the electrostatic discharge is required to rise in order to restrain occurrence of a field failure after shipping the device.

For instance, the heat sink of the notebook type personal computer is composed of cooper or aluminum exhibiting high heat transferability. Moreover, a majority of heat sinks are of an air cooling type and are therefore disposed in the vicinities of an air intake and an air exhaust, which can be visually recognized from outside. There is a possibility that static electricity flows into interiors of the air intake and the air exhaust from an electrostatically charged human body etc. Herein, the heat sink is configured in a state of being plated with nickel etc or smoothing the surface, but any measure against the electrostatic discharge is not taken into consideration. Hence, the CPU and the chipset are directly affected by the static electricity of the heat sinks. Accordingly, if the static electricity is dispersed to the heat sinks disposed in the interiors of the air intake and the air exhaust, the static electricity flows to the CPU and the chipset each exhibiting the low electromotive force, resulting in such a case that the device as a while gets into a malfunction and the CPU is damaged. This is a problem related to a quality of the electronic device and might become one factor of the field failure. A measure against the electrostatic discharge in the heat sink has hitherto been made in the whole device, which was one factor of a rise in manufacturing cost.

Such being the case, it is an object of the embodiments discussed herein to provide a heat sink which reduces an electric influence on an electronic device even when a discharge phenomenon occurs on a heat sink surface.

The embodiments discussed herein, for solving the problems described above, restricts a discharge current flowing to between a tangible object vicinal to a heat sink surface and a radiating unit.

Specifically, a heat sink includes: a conductive radiating unit radiating heat of an electronic component into the air; and a current restricting unit disposed on a heat sink surface of the radiating unit and restricting, when a discharge phenomenon occurs between a tangible object vicinal to the heat sink surface and the radiating unit, a discharge current flowing to between the tangible object and the radiating unit.

A potential difference between the tangible object vicinal to the heat sink surface and the radiating unit spreads, and, if this potential difference exceeds a potential difference enabling insulation of the air existing between the tangible object and the radiating unit, the discharge phenomenon occurs between the tangible object and the radiating unit. The discharge phenomenon in the air, though dependent greatly on conditions such as a temperature and humidity, occurs generally between objects having a potential difference on the order of several kilo volts. An inflow abnormal voltage via a power source unit, a communication line, etc can be solved by providing a circuit which absorbs the abnormal voltage. On the other hand, the heat sink needs to exchange the heat with the electronic component, and hence the circuit which absorbs the abnormal voltage can not be provided between the heat sink and the electronic component.

Such being the case, the heat sink according to the embodiments discussed herein reduces the electric influence on the electronic component by providing the current restricting unit which restricts the discharge current on the heat sink surface of the radiating unit. Namely, the discharge current flowing to between the tangible object and the radiating unit is restricted by providing the current restricting unit, thus restraining fluctuations in potential of the radiating unit. On the occasion of occurrence of the discharge phenomenon, the fluctuations in potential of the radiating unit are restrained, thereby reducing the electric influence on the electronic component connected to the radiating unit.

As described above, the heat sink according to the embodiments discussed herein can reduce, even when the discharge phenomenon occurs on the heat sink surface, the electric influence exerted on the electronic device.

Herein, the current restricting unit may be configured with projections formed by executing a notching work on the heat sink surface, and may restrict the discharge current with electric resistance of the projections.

A conductive substance has a limit of a quantity of electrons enabled to exist inside and therefore has an upper limit of a value of the current enabled to flow. Hence, if a sectional area of the conductive substance through which the current flows is restricted, resistance is caused in the current flowing through this restricted area, resulting in occurrence of a potential difference. Further, the discharge phenomenon appears between portions with the smallest electric resistance in the air and with the shortest linear distance. Hence, the projections are provided on the heat sink surface, and the discharge phenomenon can be generated between the tips of the projections and the tangible object vicinal to the heat sink surface. Herein, according to the embodiments discussed herein, the current enabled by the projections to flow can be decreased by thinning, e.g., the tips of the projections or thinning the whole of the projections. This contrivance restricts the discharge current flowing when the discharge phenomenon appears and restrains the fluctuations in potential of the radiating unit.

Herein, the current restricting unit may be configured by executing rough surface working on the heat sink surface, and may restrict the discharge current with the electric resistance of the rough surface.

According to this configuration, when the discharge current flows to between the tangible object vicinal to the heat sink surface and the radiating unit, the electric resistance is caused by minute ruggedness on the heat sink surface undergoing the rough surface working to thereby restrict the discharge current flowing to the radiating unit, and the fluctuations in potential of the radiating unit is restrained.

Herein, the current restricting unit may be subjected to a rustproofing treatment or a plating treatment conducted on its surface.

According to this scheme, the surface of the current restricting unit is protected by the rustproofing treatment or the plating treatment, and it is therefore feasible to restrain a melting damage etc due to the discharge and to enhance tolerance against the aerial discharge.

Herein, the radiating unit may radiate the heat of the electronic component disposed within an electronic device into the air via a vent hole provided in a housing of the electronic device, and the current restricting unit may be positioned between the radiating unit and this aperture and may restrict, when the discharge phenomenon occurs between the radiating unit and the tangible object existing in the periphery of the electronic device, the discharge current flowing to between the tangible object and the radiating unit.

Generally, the cooling type heat sink built in the electronic device is disposed in the vicinity of the vent hole provided in the housing of the electronic device in order to facilitate an exposure of the radiating unit to the outside air. The vent hole needs to admit a transmission of the air and is therefore hard to prevent inflows of electric noises, static electricity, etc. When the electric noises, the static electricity, etc entering the vent hole reach an internal electronic circuit via the heat sink, the device is induced to a malfunction and a fault. Such being the case, a scheme of the embodiments discussed herein are that the current restricting unit is disposed between the aperture and the radiating unit. With this scheme, when the discharge phenomenon occurs between the tangible object existing in the vicinity of the vent hole and the radiating unit, it is possible to restrain the fluctuations in potential of the radiating unit and to restrain the malfunction and the fault of the electronic device.

Herein, the current restricting unit may be disposed in a position that can be visually recognized from the outside via the vent hole.

According to this configuration, the discharge current emitted from the tangible object existing in the vicinity of the vent hole is transferred to the radiating unit via the current restricting unit, so that the discharge current is restricted to thereby restrain the fluctuations in potential of the radiating unit.

It is feasible to provide the heat sink which reduces the electric influence exerted on the electronic device even when the discharge phenomenon occurs on the heat sink surface.

All example and conditional language recited herein are intended for pedagogical purposes to aid the reader in understanding the invention and the concepts contributed by the inventor to furthering the art, and are to be construed as being without limitation to such specifically recited examples and conditions, nor does the organization of such example in the specification relate to a showing of the superiority and inferiority of the invention. Although the embodiment(s) of the present invention(s) has (have) been described in detail, it should be understood that the various changes, substitutions, and alterations could be made hereto without departing from the spirit and scope of the invention.

What is claimed is:

1. A heat sink comprising:
a conductive radiating unit including a heat sink surface and radiating heat of an electronic component from the heat sink surface into the air; and
a current restricting unit provided in a portion, vicinal to a tangible object, on the heat sink surface of said radiating unit, and restricting, when a discharge phenomenon occurs between the tangible object and said radiating unit, a discharge current flowing to between the tangible object and said radiating unit.

2. The heat sink according to claim 1, wherein said current restricting unit is configured with projections formed by notching only the portion, vicinal to the tangible object, on the heat sink surface, and restricts the discharge current with electric resistance of the projections.

3. The heat sink according to claim 1, wherein said current restricting unit is configured by executing rough surface working only the portion, vicinal to the tangible object, on the heat sink surface, and restricts the discharge current with the electric resistance of the rough surface.

4. The heat sink according to claim 1, wherein said current restricting unit is subjected to a rustproofing treatment or a plating treatment conducted on its surface.

5. The heat sink according to claim 1, wherein said radiating unit radiates the heat of the electronic component disposed within an electronic device into the air via a vent hole provided in a housing of the electronic device, and
said current restricting unit is positioned between said radiating unit and the vent hole and restricts, when the discharge phenomenon occurs between said radiating unit and the tangible object existing in the periphery of the electronic device, the discharge current flowing to between the tangible object and said radiating unit.

6. The heat sink according to claim 1, wherein said current restricting unit is disposed in a position that can be visually recognized from the outside via the vent hole.
